(19) United States
(12) Patent Application Publication
(10) Pub. No.: US 2015/0159266 A1
(43) Pub. Date: Jun. 11, 2015

(54) METHOD OF MANUFACTURING FLEXIBLE SUBSTRATE ALLOWING ELECTRONIC DEVICE TO BE MOUNTED THERETO

(71) Applicant: Electronics and Telecommunications Research Institute, Daejeon (KR)

(72) Inventors: Sang Chul LIM, Daejeon (KR); Jae Bon KOO, Daejeon (KR); Chan Woo PARK, Daejeon (KR); Soon-Won JUNG, Daejeon (KR); Bock Soon NA, Daejeon (KR); Sang Seok LEE, Sejong (KR); Kyoung Ik CHO, Daejeon (KR); Hye Yong CHU, Daejeon (KR)

(73) Assignee: Electronics and Telecommunications Research Institute, Daejeon (KR)

(21) Appl. No.: 14/282,980

(22) Filed: May 20, 2014

(30) Foreign Application Priority Data
Dec. 10, 2013 (KR) 10-2013-0153193

(51) Int. Cl. C23C 16/02; C23C 16/04; C23C 16/06

(52) U.S. Cl. CPC C23C 16/0254; C23C 16/06; C23C 16/042

(57) ABSTRACT

Provided is a method of manufacturing a flexible substrate allowing an electronic device to be mounted thereto. The method of manufacturing a flexible substrate allowing an electronic device to be mountable thereto, includes preparing a substrate, applying a force to the substrate to stretch the substrate in horizontal direction, performing a surface treatment process on the substrate and forming a first region having a plurality of wavy surfaces, and forming an electrode on the first region.

### CROSS-REFERENCE TO RELATED APPLICATIONS

This U.S. non-provisional patent application claims priority under 35 U.S.C. §119 of Korean Patent Application No. 10-2013-0153193, filed on Dec. 10, 2013, the entire contents of which are hereby incorporated by reference.

### BACKGROUND OF THE INVENTION

The present invention disclosed herein relates to a method of manufacturing a flexible substrate allowing an electronic device to be mounted thereto, and more particularly, to a method of manufacturing a flexible substrate allowing an electronic device to be mounted thereto, wherein reliability is improved.

Currently, display apparatuses visually represent information input in various schemes such that a human can recognize. In order to visually representing the information input to the display device, an electronic device is necessary to be driven.

Nowadays, the electronic device for driving the current display device tends to be miniaturized and highly integrated, and is applied to application fields, such as a flexible display field, a medical industry field applicable to electronic skin, and a sensor field. The electronic device applied to the applications is required not to be damaged by external stress. Accordingly, the electronic device is applicable to the applications by being mounted on a stretchable substrate which can be freely bent or folded.

Fabrication of waves on the stretchable substrate has benefits in that metal interconnections formed on the substrate are not cut or damaged even when the substrate is stretched. Accordingly, wave fabricating methods has been variously proposed.

### SUMMARY OF THE INVENTION

The present invention provides a method of manufacturing a flexible substrate allowing an electronic device to be mounted thereto, wherein reliability is improved.

Embodiments of the present invention provide methods of manufacturing a flexible substrate allowing an electronic device to be mountable thereto, the method including: preparing a substrate; applying a force to the substrate to stretch the substrate in horizontal direction; performing a surface treatment process on the substrate and forming a first region having a plurality of wavy surfaces; and forming an electrode on the first region.

In some embodiments, the surface treatment process may be any one of an ultraviolet-ozone (UV-O3) process, an O2 plasma process, and a sputtering plasma process.

In other embodiments, the forming of the first region comprises, disposing a mask having an opening on the substrate; and performing the surface treatment process on the mask to activate a surface of the first region of the substrate which is exposed by the opening.

In still other embodiments, the activating of the surface of the first region may include modifying a surface of the first region from a hydrophobic surface into a hydrophilic surface.

In even other embodiments, the plurality of wavy surfaces may have a constant width and repeated in a constant period.

In yet other embodiments, the width of the wavy surfaces may become wider as plasma intensity is stronger and a plasma treatment time is longer in the surface treatment process.

In further embodiments, the applying of the force to the substrate may include stretching a horizontal length of the substrate by 1% to 40% than that before being stretched.

In still further embodiments, the forming of the electrode may include conformally applying a metal material to the first region along the wavy surfaces.

In even further embodiments, the electrode may include tungsten (W), copper (Cu), aluminum (Al), chromium (Cr), molybdenum (Mo), silver (Al), or gold (Au).

In yet further embodiments, the substrate may further include a second region, wherein the second region is a region that is not exposed to the surface treatment process and an electronic device is formed on the second region.

In much further embodiments, the method may further include removing the force applied to the substrate after forming the electrode on the first region.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a flowchart illustrating a method of manufacturing a flexible substrate according to an embodiment of the present invention;

FIGS. 2A to 2F are perspective views illustrating a method of manufacturing a flexible substrate according to an embodiment of the present invention;

FIG. 3 is a perspective view illustrating a method of manufacturing a flexible substrate according to an embodiment of the present invention, wherein a part A of FIG. 2D is enlarged;

FIG. 4 is a perspective view illustrating a method of manufacturing a flexible substrate according to an embodiment of the present invention, wherein a part B of FIG. 2E is enlarged; and

FIGS. 5A to 5C are perspective views illustrating a deformed size of a flexible substrate according to plasma intensity and plasma treatment time in a surface treatment process according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional views and/or plan views that are schematic illustrations of example embodiments. In the drawings, the thicknesses of layers and regions are exaggerated for clarity. As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. For example, an implanted region illustrated as a rectangle may, typically, have rounded or curved features. Thus, the regions illustrated in the figures are schematic in nature and their shapes may be not intended to illustrate the actual shape of a region of a device and are not intended to limit the scope of example embodiments.

Hereinafter, it will be described about an exemplary embodiment of the present invention in conjunction with the accompanying drawings.

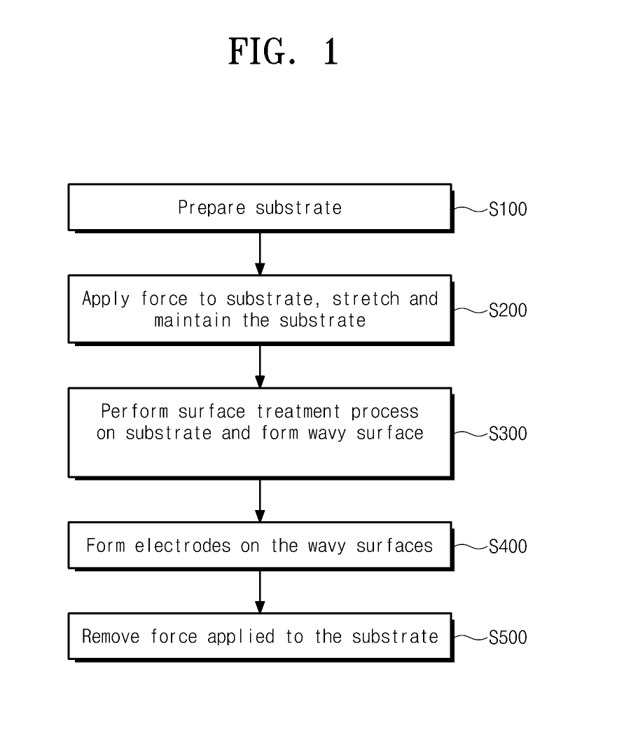

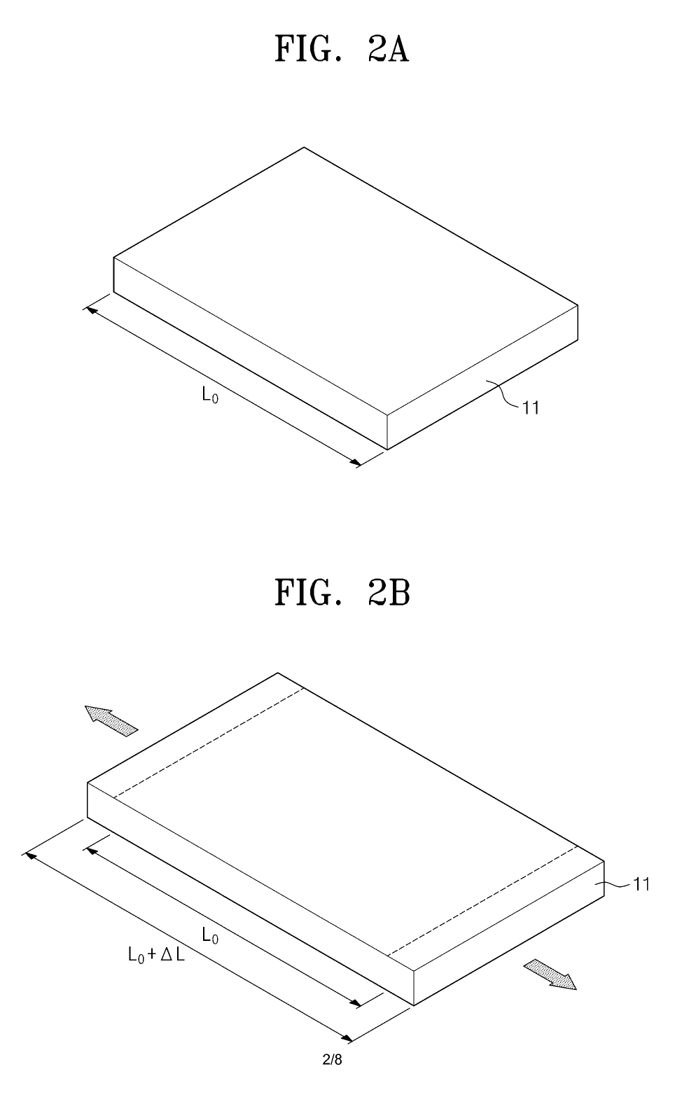

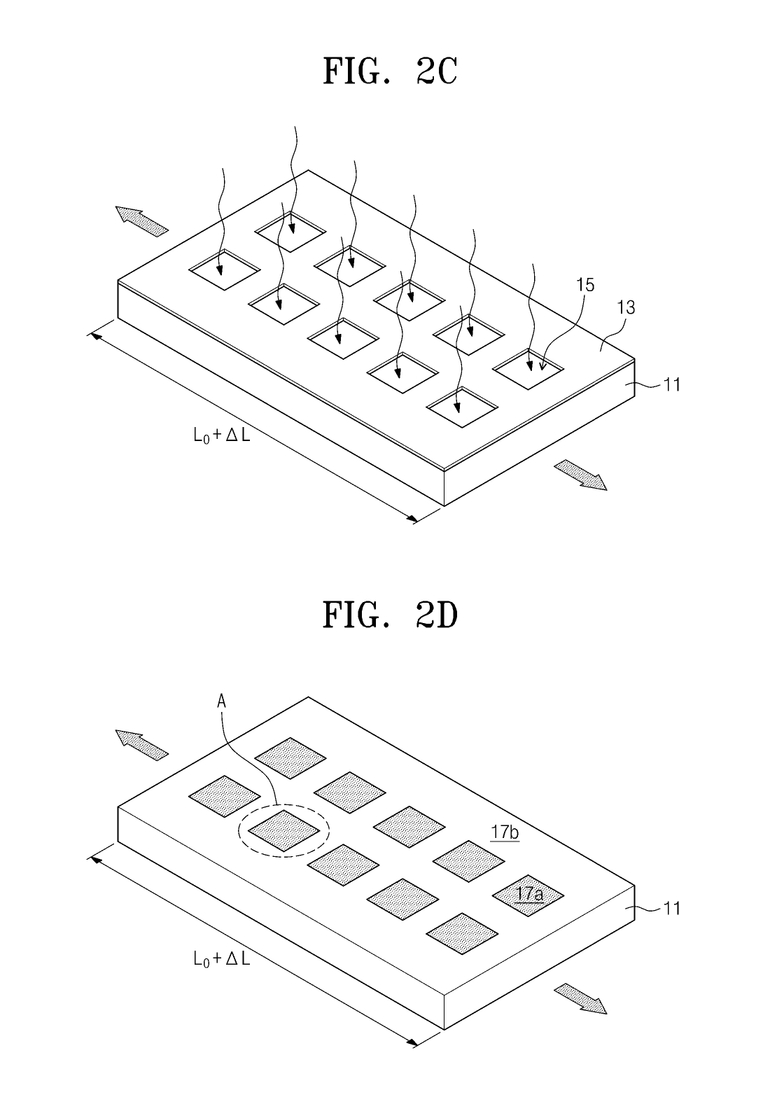

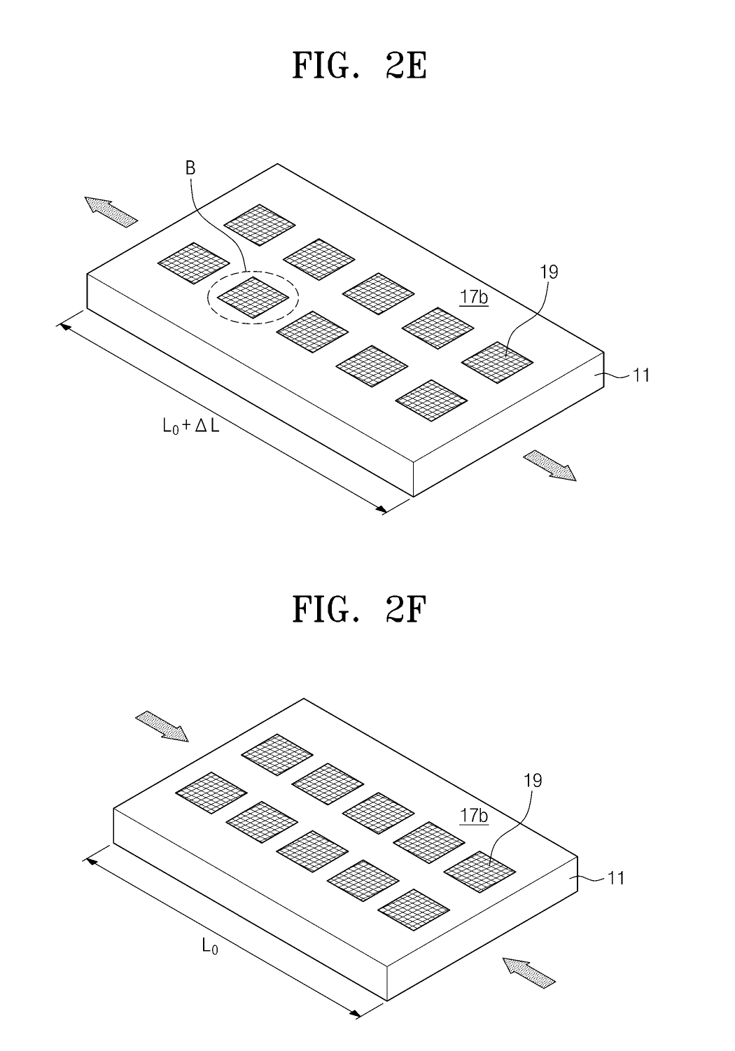

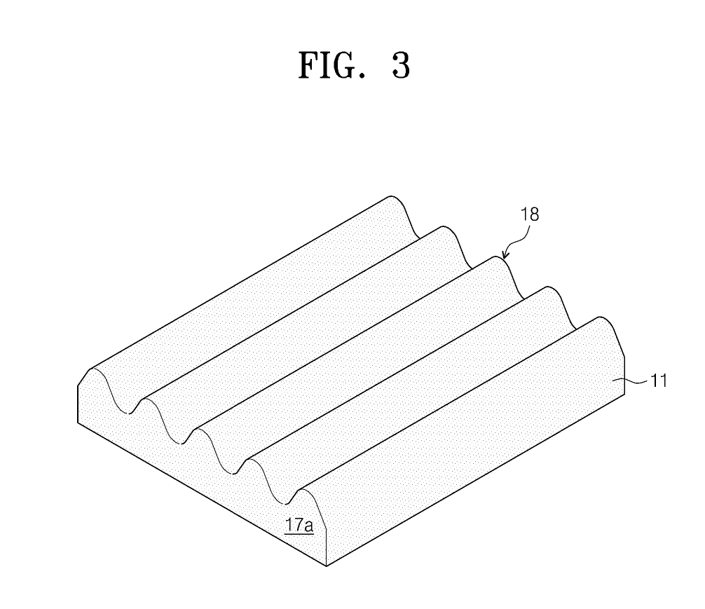

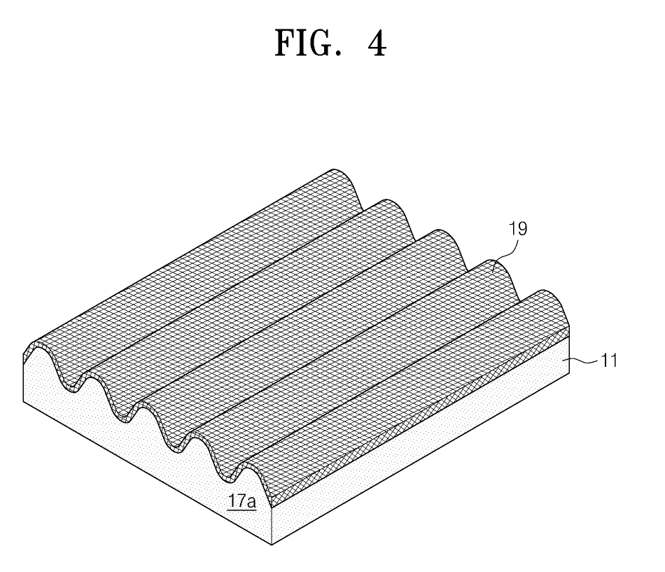

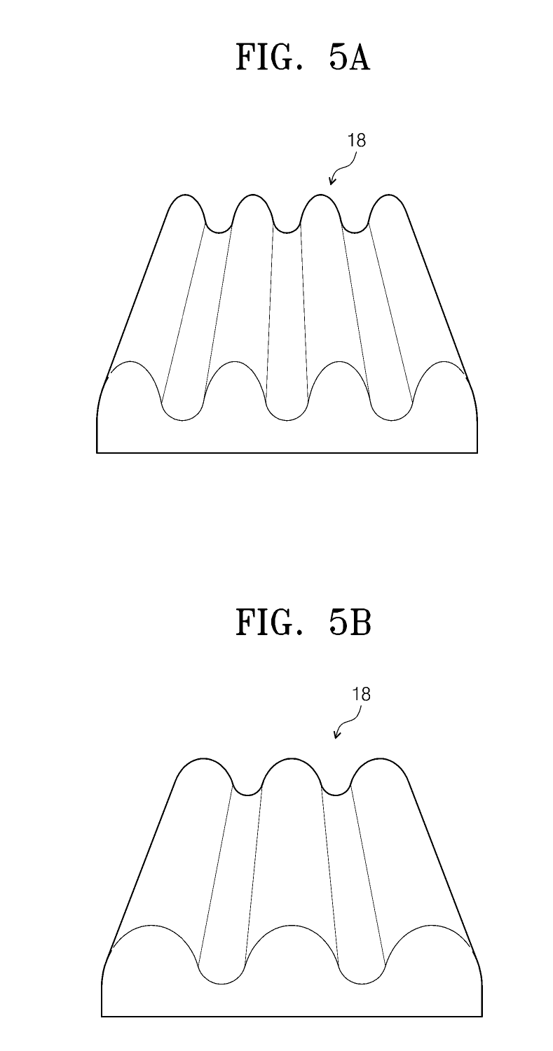

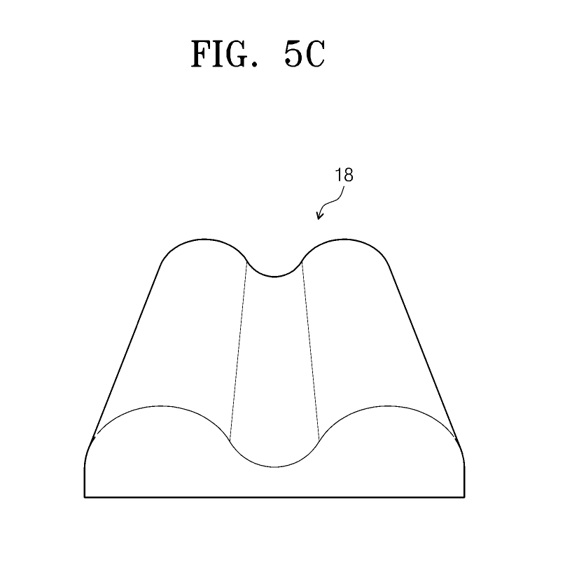

FIG. 1 is a flowchart illustrating a method of manufacturing a flexible substrate according to an embodiment of the present invention. FIGS. 2A to 2F are perspective views illustrating a method of manufacturing a flexible substrate according to an embodiment of the present invention. FIG. 3 is a perspective view illustrating a method of manufacturing a flexible substrate according to an embodiment of the present invention, wherein a part A of FIG. 2D is enlarged. FIG. 4 is a perspective view illustrating a method of manufacturing a flexible substrate according to an embodiment of the present invention, wherein a part B of FIG. 2E is enlarged. FIGS. 5A to 5C are perspective views illustrating a deformed size of a flexible substrate according to plasma intensity and plasma treatment time in a surface treatment process according to an embodiment of the present invention.

Referring to FIGS. 1 and 2A, a substrate 11 is prepared (step S100). The substrate 11 may be a flexible substrate having elasticity, for example, a ploydimethylsiloxane (PDMS) substrate, a polymer substrate, or a rubber substrate.

A method of forming the substrate 11 is described. According to an embodiment, elastomer material (for example, liquid phase PDMS) and a curing agent (for example, dimethyl methylhydrogen siloxane) are mixed at a ratio of about 10:1 and a mixed solution is formed. After the mixed solution is formed, the mixed solution is put inside a vacuum chamber and kept about several hours in order to remove bubbles included in the mixed solution. The bubble-removed mixed solution is put inside an oven and coated by a dry or spin-coating method for about 2 hours to form the substrate 11. When the substrate 11 is formed by the spin-coating method, the thickness of the substrate 11 may be adjusted by adjusting a revolution speed (rpm) and time.

Referring to FIGS. 1 and 2B, the substrate 11 is stretched and maintained by applying a force (step S200). In detail, the substrate 11 may be stretched by applying a force and pulling it in one side or both sides by using equipment capable of stretching the substrate 11. The substrate 11 may be stretched by ΔL, and ΔL may be about 1% to about 40% of the horizontal length L₀ of the substrate 11.

Referring to FIGS. 1, 2C, 2D, and 3, a surface treatment process is performed on the substrate 11 and wavy surfaces 18 are formed on the substrate 11 (step S300). The surface treatment process is performed on a mask 13 by disposing the mask 13 having openings 15 on the substrate 11. With the surface treatment process, the wavy surfaces 18 may be formed locally on the surface of the substrate 11 exposed by the openings 15. Regions on which the wavy surfaces 18 are formed are interconnection regions 17a and the remaining region except the interconnection regions 17a is a device region 17b. That is, the interconnection regions 17a are regions on which the interconnections connecting electronic devices are formed, and the device region 17b is a region on which the electronic devices are disposed. The device region 17b of the substrate 11, which is not exposed on the surface treatment process, maintains a flat surface. The surface treatment process may be, for example, an ultraviolet-ozone (UV-O₃) process, an O₂ plasma process, or a sputtering plasma process.

The UV-ozone (UV-O₃) process is a surface treatment process using ozone O₃. In detail, ozone O₃ is generated through a UV ozone processing apparatus and the ozone activates the surface of the substrate 11. Accordingly, the surface of the substrate 11 changes from a hydrophobic surface into a hydrophilic surface.

The O₂ plasma process is a surface treatment process using oxygen plasma ions. In detail, oxygen plasma ions (O²⁻ ions) are generated through an oxygen gas in a plasma generating apparatus. The O²⁻ ions activate and are combined with the surface of the substrate 11. The O²⁻ ion combined surface of the substrate 11 is changed from a hydrophobic surface into a hydrophilic surface.

The surface treatment process may cause surface oxidation of the substrate 11. For example, when the substrate 11 is a PDMS substrate, —CH₃ of an end group having strong hydrophobicity, which is combined with the surface of the substrate 11, is substituted with —O or —OH group to allow the surface of the substrate 11 to have a covalent bond of a Si—O—Si structure having strong hydrophilicity. The substrate 11 modified to have strong hydrophilicity by the surface treatment is an oxidized region, namely, the interconnection regions 17a, and the wavy surfaces 18 may be formed on the interconnection regions 17a.

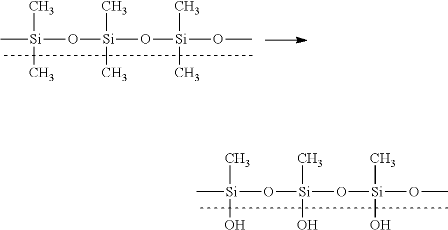

One or more wavy surfaces 18 may be formed on the interconnection regions 17a. When the interconnection regions 17a are formed of a plurality of wavy surfaces 18, the wavy surfaces 18 have a constant width and may be repeated in a constant period. The width of the wavy surfaces 18 may be differed by adjusting plasma intensity and plasma treatment time in the surface treatment process.

In detail, referring to FIGS. 5A to 5C, as the plasma intensity is stronger and the plasma treatment time is longer in the surface treatment process, the wavy surfaces 18 may be formed to have a larger width.

When the wavy surfaces 18 are formed on the entire surface of the substrate 11, the disposition of the mask 13 may be omitted and the surface treatment process may be performed.

Referring to FIGS. 2E and 4, electrodes 19 are formed on the interconnection regions 17a of the substrate 11 (step 400). The electrodes 19 may be formed conformally on the interconnection regions 17a along the wavy surfaces 18. The electrodes 19 may be formed by using a chemical vapor deposition (CVD), a physical vapor deposition (PVP), or an atom layer deposition (ALD). The electrode 19 may include a metal material, such as tungsten (W), copper (Cu), aluminum (Al), chromium (Cr), molybdenum (Mo), silver (Al), or gold (Au).

Referring to FIGS. 1 and 2F, the force applied to the substrate 11 is removed (step S500). Accordingly, the substrate 11 returns to have the initial horizontal length L₀. The electrodes 19 formed on the substrate 11 may maintain their shapes without deformation or brokenness, although the substrate 11 is stretched by about Lo+ΔL.

Although not shown in the drawing, an electronic device (not shown) may be formed on the device region 17b of the substrate 11. The electronic device may be a transistor.

According to an embodiment of the present invention, the interconnection regions 17a of the substrate 11, which have the wavy surfaces 18, may be formed by the surface treatment process. Accordingly, despite of bending or pulling of the substrate 11, the electrodes 19 formed on the interconnection regions 17a can be prevented from being damaged and the electronic device formed on the device region 17b can be stably driven. Furthermore, since the width and period of the wavy surfaces 18 can be adjusted according to process conditions in the surface treatment process, the substrate 11 can be used in various fields.

According to a method of manufacturing a flexible substrate that an electronic device is mountable according to an embodiment, interconnections can be formed on the substrate having wavy surfaces by the surface treatment process. Accordingly, an electronic device formed on a device region can be stably driven by preventing damages on the interconnections formed on an interconnection region.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of manufacturing a flexible substrate allowing an electronic device to be mountable thereto, the method comprising:
preparing a substrate;
applying a force to the substrate to stretch the substrate in horizontal direction;
performing a surface treatment process on the substrate and forming a first region having a plurality of wavy surfaces; and
forming an electrode on the first region.

2. The method according to claim 1, wherein the surface treatment process is any one of an ultraviolet-ozone (UV-O₃) process, an O₂ plasma process, and a sputtering plasma process.

3. The method according to claim 2, wherein the forming of the first region comprises,
disposing a mask having an opening on the substrate; and
performing the surface treatment process on the mask to activate a surface of the first region of the substrate which is exposed by the opening.

4. The method according to claim 3, wherein the activating of the surface of the first region comprises modifying a surface of the first region from a hydrophobic surface into a hydrophilic surface.

5. The method according to claim 1, wherein the plurality of wavy surfaces have a constant width and repeated in a constant period.

6. The method according to claim 5, wherein the width of the wavy surfaces become wider as plasma intensity is stronger and a plasma treatment time is longer in the surface treatment process.

7. The method according to claim 1, wherein the applying of the force to the substrate comprises stretching a horizontal length of the substrate by 1% to 40% than that before being stretched.

8. The method according to claim 1, wherein the forming of the electrode comprises conformally applying a metal material to the first region along the wavy surfaces.

9. The method according to claim 1, wherein the electrode comprises tungsten (W), copper (Cu), aluminum (Al), chromium (Cr), molybdenum (Mo), silver (Al), or gold (Au).

10. The method according to claim 1, wherein the substrate further comprises a second region, wherein the second region is a region that is not exposed to the surface treatment process and an electronic device is formed on the second region.

11. The method according to claim 1, further comprising removing the force applied to the substrate after forming the electrode on the first region.
